(19) United States
(12) Patent Application Publication
(10) Pub. No.: US 2026/0176530 A1
(43) Pub. Date: Jun. 25, 2026

(54) ETCHING COMPOSITION, ETCHING METHOD, AND METHOD FOR MANUFACTURING SEMICONDUCTOR SUBSTRATE

(71) Applicant: TOKYO OHKA KOGYO CO., LTD., Kanagawa (JP)

(72) Inventors: Shogo MIYANO, Kanagawa (JP); Choitsu GO, Kanagawa (JP)

(21) Appl. No.: 19/425,168

(22) Filed: Dec. 18, 2025

(30) Foreign Application Priority Data
Dec. 23, 2024 (JP) 2024-226374

(51) Int. Cl. C09K 13/08; C09K 13/00; H10P 50/24

(52) U.S. Cl. CPC C09K 13/08; C09K 13/00; H10P 50/242

(57) ABSTRACT

Provided are an etching composition containing (A) an oxidizing agent; (B) a compound capable of releasing fluoride ions or a salt thereof; and (C) a nonionic surfactant containing at least one selected from the group consisting of a compound (c1) having a specific structure and a compound (c2) having a specific structure, an etching method, and a method for manufacturing a semiconductor substrate.

### CROSS-REFERENCE TO RELATED APPLICATIONS

The present application claims priority based on Patent Application No. 2024-226374 filed with the Japan Patent Office on Dec. 23, 2024, the entire contents of which are incorporated herein by reference.

### BACKGROUND OF THE INVENTION

### 1. Technical Field

The present invention relates to an etching composition, an etching method, and a method for manufacturing a semiconductor substrate.

### 2. Description of the Related Art

In recent years, in semiconductor manufacturing processes, miniaturization of wiring and an increase in the number of laminated layers have been advancing. In such manufacturing processes accompanied by miniaturization and an increase in the number of laminated layers, silicon germanium alloys (SiGe, hereinafter, may be simply referred to as “silicon germanium”) are used. SiGe is obtained by adding germanium to silicon, and has advantages such as higher conductivity, low power consumption, and reduced susceptibility to noise, compared with silicon alone.

For example, in the case of manufacturing an LSI or the like, when introducing a strained Si on Insulator (SOI) structure, an SiGe layer is used as a buffer layer. More specifically, on a silicon substrate, an SiGe layer having a high germanium concentration is laminated as a sacrificial film, and an SiGe layer having a low germanium concentration is further laminated thereon, and a laminate obtained in this manner is employed.

As an etching solution used for etching such a laminate, for example, Patent Literature 1 discloses a composition for selectively etching a layer containing a silicon germanium alloy (SiGe) in the presence of a silicon-containing layer, particularly a layer containing α-Si, SiOx, SiON, SiN, or a combination thereof, the composition containing (a) an oxidizing agent; (b) an acid selected from an inorganic acid and an organic acid; (c) an etching solution containing a fluoride ion source; (d) polyvinylpyrrolidone (PVP); and (e) water.

### PATENT LITERATURE

Patent Literature 1: WO 2021/004759 A

### SUMMARY OF THE INVENTION

However, there is still room for improvement in the etching in semiconductor manufacturing processes using the above-described SiGe.

First, in the case of etching a laminate in which, on a silicon substrate, an SiGe layer having a high germanium concentration is laminated as a sacrificial film and an SiGe layer having a low germanium concentration is further laminated thereon, it is required that the SiGe layer having a high germanium concentration can be etched while causing no damage to the other SiGe layers (selectivity for SiGe). In addition, it is required that no damage is caused to the silicon layer (such as the silicon substrate) (suppression of damage to Si). However, conventional etching solutions do not sufficiently achieve the selectivity for SiGe and the suppression of damage to the silicon layer.

Second, the conventional etching solution has room for improvement in defoaming properties of the etching solution. In an actual manufacturing process, an etching treatment is performed in a tank in which the etching solution is stored and in an etching apparatus connected thereto. The etching solution used in the etching treatment is delivered from a drain connected to the etching apparatus to a tank, and the used etching solution is refilled into the tank, thereby circulating the etching solution. In addition, for safety management during operation, the tank is provided with a water-level detection unit, such as a water-level meter or a tank gauge, and, when the water level of the etching solution exceeds a reference value during operation, the water-level detection unit detects this and stops the operation, such that such a function is provided.

When bubbles are generated in the etching solution at the time of circulating the etching solution or during operation, the apparent water level becomes higher than the actual water level, and, even though the water level does not exceed the reference water level, the water-level detection unit may erroneously detect that the water level exceeds the reference water level. As a result, the operation of the etching apparatus is stopped, and the production efficiency decreases.

The present invention has been made in view of the above circumstances, and an object of the present invention is to provide an etching composition having excellent selectivity for SiGe, excellent suppression of damage to Si, and excellent defoaming properties, an etching method, and a method for manufacturing a semiconductor substrate.

As a result of intensive studies to achieve the above object, the present inventors have found that an etching composition accomplishes the above object, the etching composition containing (A) an oxidizing agent; (B) a compound capable of releasing fluoride ions or a salt thereof, and (C) a nonionic surfactant containing at least one selected from the group consisting of a compound (c1) having a specific structure and a compound (c2) having a specific structure, thereby completing the present invention.

That is, the present invention is as follows.

<1>

An etching composition containing: (A) an oxidizing agent; (B) a compound capable of releasing fluoride ions or a salt thereof; and (C) a nonionic surfactant containing at least one selected from the group consisting of a compound (c1) represented by the following General Formula (c1) and a compound (c2) represented by the following General Formula (c2).

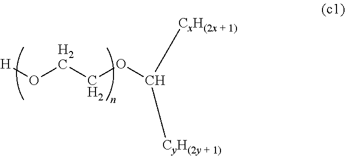

In General Formula (c1), x, y, and n represent numbers of 1 or more.

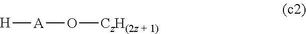

In General Formula (c2), A is a divalent group containing a structural unit (c2-1) represented by the following Formula (c2-1) and a structural unit (c2-2) represented by the following Formula (c2-2), and z represents a number of 1 or more.

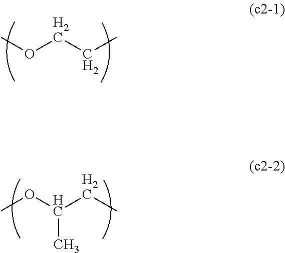

<2>

The etching composition according to <1>, in which the component (A) includes at least one selected from the group consisting of hydrogen peroxide and an oxo acid.

<3>

The etching composition according to <1> or <2>, in which the component (B) is at least one selected from the group consisting of hydrogen fluoride, ammonium fluoride, ammonium hydrogen fluoride, triethanolammonium fluoride, diglycolammonium fluoride, methyldiethanolammonium fluoride, tetramethylammonium fluoride, triethylamine trihydrofluoride, fluoroboric acid, tetrafluoroboric acid, ammonium tetrafluoroborate, fluoroacetic acid, ammonium fluoroacetate, trifluoroacetic acid, fluorosilicic acid, ammonium fluorosilicate, and tetrabutylammonium tetrafluoroborate.

<4>

The etching composition according to <1> or <2>, in which a content of the component (A) is 0.01 to 20 mass %.

<5>

The etching composition according to <4>, in which a content of the component (B) is 0.01 to 10 mass %.

<6>

The etching composition according to <1> or <2>, in which a content of the component (C) is 0.0001 to 3 mass %.

<7>

The etching composition according to <1> or <2>, further containing water.

<8>

The etching composition according to <7>, in which the etching composition has a pH of 6 or less.

<9>

The etching composition according to <1> or <2>, in which the etching composition is an etching composition for selectively etching a layer containing a silicon germanium alloy (SiGe).

<10>

An etching method including etching a laminated substrate including a substrate and a layer provided on the substrate and containing a silicon germanium alloy (SiGe) using an etching composition, in which the etching composition contains (A) an oxidizing agent; (B) a compound capable of releasing fluoride ions or a salt thereof; and (C) a nonionic surfactant containing at least one selected from the group consisting of a compound (c1) represented by the following General Formula (c1) and a compound (c2) represented by the following General Formula (c2).

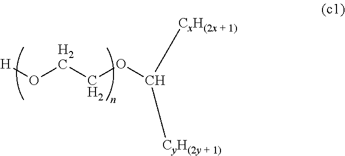

In General Formula (c1), x, y, and n represent numbers of 1 or more.

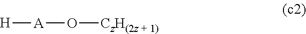

In General Formula (c2), A is a divalent group containing a structural unit (c2-1) represented by the following Formula (c2-1) and a structural unit (c2-2) represented by the following Formula (c2-2), and z represents a number of 1 or more.

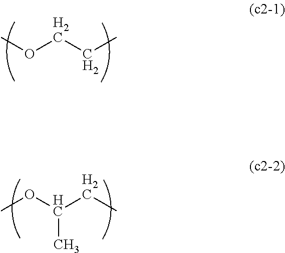

<11>

A method for manufacturing a semiconductor substrate, the method including: etching a laminated substrate including a substrate and a layer provided on the substrate and containing a silicon germanium alloy (SiGe) using an etching composition; and cleaning the etched laminated substrate with a cleaning solution, in which the etching composition contains (A) an oxidizing agent; (B) a compound capable of releasing fluoride ions or a salt thereof; and (C) a nonionic surfactant containing at least one selected from the group consisting of a compound (c1) represented by the following General Formula (c1) and a compound (c2) represented by the following General Formula (c2).

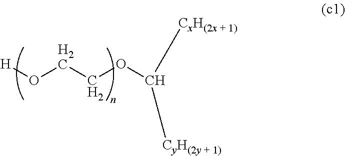

In General Formula (c1), x, y, and n represent numbers of 1 or more.

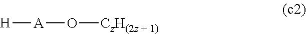

In General Formula (c2), A is a divalent group containing a structural unit (c2-1) represented by the following Formula (c2-1) and a structural unit (c2-2) represented by the following Formula (c2-2), and z represents a number of 1 or more.

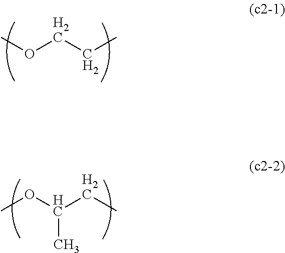

According to the present invention, it is possible to provide an etching composition having excellent selectivity for SiGe, excellent suppression of damage to Si, and excellent defoaming properties, an etching method, and a method for manufacturing a semiconductor substrate.

### DETAILED DESCRIPTION

Hereinafter, an embodiment for carrying out the present invention (hereinafter, simply referred to as “the present embodiment”) will be described in detail. The following present embodiment is an example for describing the present invention, and is not intended to limit the present invention to the following contents. The present invention can be appropriately modified and implemented within the scope of the gist thereof. In addition, the configurations and parameters disclosed in the present specification can be any combination unless otherwise specified. Furthermore, an upper limit and a lower limit of the values disclosed in the present specification can be any combination unless otherwise specified.

In addition, in the present specification, the term “comprise” or “contain” may be replaced with “consist essentially of” and “consist of” as necessary. Further, the expression “A and/or B” means “A, B, or both”, unless otherwise specified.

Note that, in the present specification, the expression “doing something or to do something” may refer to “process” or “step”, “process” may refer to “doing something or to do something” or “step”, and “step” may refer to “doing something or to do something” or “process”. In addition, in the present specification, the term “process” such as “step” may refer to “apparatus or unit that is configured to perform the step”, the term “apparatus” may refer to “mechanism or unit”, and the term “unit” may refer to “unit or apparatus provided for a mechanism, an apparatus, or a system”.

### <Etching Composition>

An etching composition according to the present embodiment is an etching composition containing (A) an oxidizing agent; (B) a compound capable of releasing fluoride ions or a salt thereof; and (C) a nonionic surfactant containing at least one selected from the group consisting of a compound (c1) represented by the following General Formula (c1) and a compound (c2) represented by the following General Formula (c2).

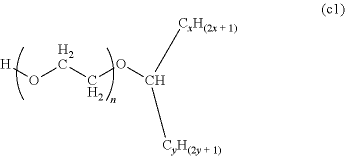

In General Formula (c1), x, y, and n represent numbers of 1 or more.

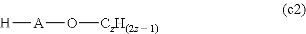

In General Formula (c2), A is a divalent group containing a structural unit (c2-1) represented by the following Formula (c2-1) and a structural unit (c2-2) represented by the following Formula (c2-2), and z represents a number of 1 or more.

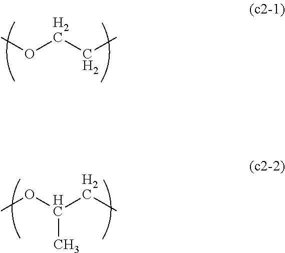

The etching composition according to the present embodiment has excellent selectivity for SiGe, excellent suppression of damage to Si, and excellent defoaming properties. Although the reason for this is not clear, it is considered that, by using a specific nonionic surfactant as the component (C) together with the component (A), which is an oxidizing agent, and the component (B), which serves as a source of fluoride ions, the selectivity between silicon germanium layers having different germanium concentrations can be improved (enhanced selectivity ratio), defoaming properties can be imparted, and suppression of damage to Si (corrosion resistance) can also be maintained (the operations and effects of the present embodiment are not limited thereto).

The etching composition according to the present embodiment is not particularly limited in the etching target and can be used for various etching applications, but the etching composition can be suitably used as an etching composition for selectively etching a layer containing a silicon germanium alloy (SiGe). In addition, the etching composition according to the present embodiment is more suitably used for etching a laminated substrate including a layer containing a silicon germanium alloy (SiGe) and/or a layer containing silicon (Si). Furthermore, the etching composition according to the present embodiment is more suitably used for etching a laminated substrate including a layer containing a silicon germanium alloy (SiGe) and silicon (Si). Furthermore, the etching composition according to the present embodiment is still more suitably used for etching a laminated substrate including a layer containing a first silicon germanium alloy (SiGe), a layer containing a second silicon germanium alloy (SiGe), and a layer containing silicon (Si), in which the first silicon germanium alloy and the second silicon germanium alloy have different germanium content ratios. The etching composition according to the present embodiment has at least the advantages of excellent selectivity for SiGe, excellent suppression of damage to Si, and excellent defoaming properties, and these advantages of the present embodiment can be effectively utilized in the etching of the laminated substrate described above.

Hereinafter, the components that may be contained in the etching composition according to the present embodiment and the characteristics thereof will be described.

### ((A) Oxidizing Agent)

The etching composition according to the present embodiment contains (A) an oxidizing agent. Thus, the metal surface can be oxidized and etched. As the oxidizing agent, it is preferable that at least one selected from the group consisting of hydrogen peroxide and an oxo acid is used.

Note that, although specific examples of using the etching composition according to the present embodiment for etching will be described below, a composition containing components other than the component (A) may be prepared in advance, and the component (A) may be mixed with the composition immediately before using the etching composition. For example, a first chemical solution containing the component (B) and the component (C) is prepared. Then, before performing etching (preferably immediately before), an etching solution may be prepared by mixing the first chemical solution described above and a second chemical solution containing the component (A), and then used. By adopting such a method of use, for example, the temporal decomposition of the oxidizing agent can be effectively suppressed, and the etching effect can be expected to be further improved.

In addition, with respect to the etching composition according to the present embodiment, when the first chemical solution and the second chemical solution are prepared separately, these chemical solutions can be used as an etching kit provided with the first chemical solution and the second chemical solution. Naturally, the etching kit is not necessarily limited to two kinds of chemical solutions, and, depending on the components, the etching kit may also be provided with chemical solutions other than the first chemical solution and the second chemical solution (e.g., a third chemical solution and a fourth chemical solution).

Specific examples of the oxo acid may include halogen oxo acids (hypochlorous acid, chlorous acid, chloric acid, perchloric acid, hypobromous acid, bromous acid, bromic acid, perbromic acid, hypoiodous acid, iodous acid, iodic acid, periodic acid, and the like), boric acid (H₃BO₃, B(OH)₃), silicic acid, nitric acid, and nitrous acid (HNO₂). In addition, the etching composition according to the present embodiment may contain these salts (e.g., sodium salts, potassium salts, calcium salts, barium salts, ammonium salts, and tetraalkylammonium salts).

Examples of the halogen oxo acids may include hypochlorous acid, chlorous acid, chloric acid, perchloric acid, hypobromous acid, bromous acid, bromic acid, perbromic acid, hypoiodous acid, iodous acid, iodic acid, and periodic acid.

Among the oxidizing agents, the oxidizing agent is preferably hydrogen peroxide or a halogen oxo acid; more preferably at least one selected from the group consisting of hydrogen peroxide, hypoiodous acid, iodous acid, iodic acid (HIO₃), and periodic acid; and still more preferably at least one selected from the group consisting of hydrogen peroxide, iodic acid, and periodic acid.

In the etching composition according to the present embodiment, above-described oxidizing agents may be used alone or in combination of two or more thereof.

A content of the component (A) in the etching composition according to the present embodiment is not particularly limited, but is preferably 0.01 to 20 mass %. The lower limit of the content is more preferably 0.05 mass % or more, still more preferably 0.08 mass % or more, and even more preferably 0.1 mass % or more. In addition, the upper limit of the content is more preferably 15 mass % or less, still more preferably 13 mass % or less, even more preferably 11 mass % or less, and yet further preferably 10 mass % or less. When the content of the component (A) is within the above range, the selectivity for SiGe, the suppression of damage to Si, and the defoaming properties can be further improved.

Note that the etching composition according to the present embodiment can achieve sufficient effects even without using an oxidizing agent other than the above hydrogen peroxide, halogen oxo acid, boric acid, silicic acid, nitric acid, and nitrous acid. From this viewpoint, the etching composition according to the present embodiment may not contain an oxidizing agent other than hydrogen peroxide, halogen oxo acid, boric acid, silicic acid, nitric acid, and nitrous acid. From a similar viewpoint, the etching composition according to the present embodiment may not contain peracetic acid as a main component.

From a similar viewpoint, the etching composition according to the present embodiment can achieve sufficient effects even without containing peracetic acid as a main component. From this viewpoint, a content of peracetic acid in the etching composition according to the present embodiment is preferably less than 0.1 mass %, more preferably less than 0.05 mass %, and still more preferably less than 0.001 mass %, and it is preferable that the etching composition does not contain peracetic acid.

From a similar viewpoint, a content of hydroxylamine in the etching composition according to the present embodiment is preferably less than 0.1 mass %, more preferably less than 0.05 mass %, and still more preferably less than 0.001 mass %, and it is preferable that the etching composition does not contain hydroxylamine.

From the viewpoint described above, it is more preferable that the etching composition according to the present embodiment does not contain peracetic acid and hydroxylamine.

### ((B) Compound Capable of Releasing Fluoride Ions and Salt Thereof)

The etching composition according to the present embodiment contains (B) a compound capable of releasing fluoride ions and a salt thereof (hereinafter, these may be collectively referred to as “fluorine-based compounds”). Specific examples of the fluorine-based compound are not particularly limited, but are preferably at least one selected from the group consisting of hydrogen fluoride (HF), hexafluorosilicic acid, ammonium fluoride, ammonium hydrogen fluoride, triethanolammonium fluoride, diglycolammonium fluoride, methyldiethanolammonium fluoride, tetramethylammonium fluoride (TMAF), triethylamine trihydrofluoride, fluoroboric acid, tetrafluoroboric acid, ammonium tetrafluoroborate, fluoroacetic acid, ammonium fluoroacetate, trifluoroacetic acid, fluorosilicic acid, ammonium fluorosilicate, and tetrabutylammonium tetrafluoroborate. Among them, the fluorine-based compound is more preferably at least one selected from the group consisting of hydrogen fluoride (HF), hexafluorosilicic acid, ammonium fluoride, ammonium hydrogen fluoride, and tetramethylammonium fluoride (TMAF), and still more preferably at least one selected from the group consisting of hydrogen fluoride, ammonium fluoride, ammonium hydrogen fluoride, and tetramethylammonium fluoride (TMAF).

Note that, in the case of hydrogen fluoride, a hydrogen fluoride solution (an aqueous solution of hydrogen fluoride, aqueous hydrogen fluoride, or aqueous HF) may be added when producing the etching composition according to the present embodiment. In addition, the salt of the compound capable of releasing fluoride ions is not particularly limited, and examples thereof may include sodium salts, potassium salts, ammonium salts, and alkylammonium salts (e.g., tetramethylammonium salts).

The components (B) may be used alone or in combination of two or more thereof.

A content of the component (B) in the etching composition according to the present embodiment is not particularly limited, but is preferably 0.01 to 10 mass %. The lower limit of the content is more preferably 0.02 mass % or more, still more preferably 0.03 mass % or more, and even more preferably 0.04 mass % or more. In addition, the upper limit of the content is more preferably 5 mass % or less, still more preferably 3 mass % or less, even more preferably 1 mass % or less, and yet further preferably 0.8 mass % or less. When the content of the component (B) is within the above range, the selectivity for SiGe, the suppression of damage to Si, and the defoaming properties can be further improved.

Note that the etching composition according to the present embodiment can achieve sufficient effects even without containing a compound capable of releasing fluoride ions other than the above hydrogen fluoride (HF), hexafluorosilicic acid, ammonium fluoride, ammonium hydrogen fluoride, and tetramethylammonium fluoride (TMAF).

### ((C) Nonionic Surfactant)

The etching composition according to the present embodiment contains (C) a nonionic surfactant containing at least one selected from the group consisting of a compound (c1) represented by General Formula (c1) and a compound (c2) represented by General Formula (c2).

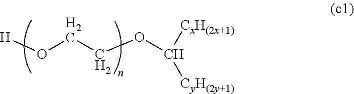

In General Formula (c1), x, y, and n represent numbers of 1 or more.

x+y in General Formula (c1) is preferably 7 to 17. The lower limit of x+y is more preferably 9 or more, and still more preferably 11 or more. In addition, the upper limit of x+y is more preferably 15 or less, and still more preferably 13 or less.

x in General Formula (c1) is preferably 1 to 16. The lower limit of x is more preferably 3 or more, and still more preferably 4 or more. In addition, the upper limit of x is more preferably 8 or less, and still more preferably 7 or less.

y in General Formula (c1) is preferably 1 to 16. The lower limit of y is more preferably 3 or more, and still more preferably 4 or more. In addition, the upper limit of y is more preferably 8 or less, and still more preferably 7 or less.

n in General Formula (c1) is preferably 1 to 15. The lower limit of n is more preferably 5 or more, and still more preferably 6 or more. In addition, the upper limit of n is more preferably 13 or less, and still more preferably 11 or less.

As suitable specific examples of the compound (c1), commercially available products such as “Softanol 90”, “TERGITOL TMN-10”, “TERGITOL TMN-6”, “Softanol 50”, “Softanol 70”, and “TERGITOL 15-S-5” may be used (see the Examples described below).

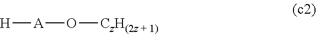

In General Formula (c2), A is a divalent group containing a structural unit (c2-1) represented by the following Formula (c2-1) and a structural unit (c2-2) represented by the following Formula (c2-2), and z represents a number of 1 or more.

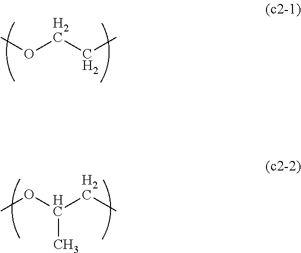

In General Formula (c2), A is a divalent group containing the structural unit (c2-1) represented by Formula (c2-1) and the structural unit (c2-2) represented by Formula (c2-2), but is preferably composed of only the structural unit (c2-1) and the structural unit (c2-2).

z in General Formula (c2) is preferably 6 to 20. The lower limit of z is more preferably 8 or more, and still more preferably 11 or more. In addition, the upper limit of z is more preferably 18 or less, and still more preferably 15 or less.

As suitable specific examples of the compound (c2), commercially available products such as “P-PE61” and “Softanol EP9050” may also be used (see the Examples described below).

The components (C) may be used alone or in combination of two or more thereof.

A content of the component (C) in the etching composition according to the present embodiment is not particularly limited, but is preferably 0.0001 to 3 mass %. The lower limit of the content is more preferably 0.0003 mass % or more and still more preferably 0.0005 mass % or more. In addition, the upper limit of the content is more preferably 2 mass % or less, still more preferably 1 mass % or less, even more preferably 0.9 mass % or less, and yet further preferably 0.8 mass % or less. When the content of the component (C) is within the above range, the selectivity for SiGe, the suppression of damage to Si, and the defoaming properties can be further improved.

The etching composition according to the present embodiment may further contain other components in addition to the component (A), the component (B), and the component (C). Examples thereof may include an accelerator, a corrosion inhibitor, a pH adjuster, a buffer, other surfactants, and a solvent, which will be described below.

### (Accelerator)

Examples of the accelerator may include components capable of improving the etching performance and promoting the etching. The accelerator is preferably a compound having two or more amino groups (NH₂—), and more preferably an aliphatic compound having two or more amino groups (NH₂—) or a cyclic compound having two or more amino groups (NH₂—). By containing such a compound as the accelerator, the selectivity for SiGe can be further improved.

Specific examples of the aliphatic compound having two or more amino groups (NH₂—) are preferably alkyl diamines such as ethylenediamine, dialkylenetriamines such as diethylenetriamine, N-(2-aminoethyl) ethanolamine, and polyethylene polyamines. Specific examples of the cyclic compound having two or more amino groups (NH₂—) are preferably cyclen and cyclam.

The accelerators may be used alone or in combination of two or more thereof.

A content of the accelerator in the etching composition according to the present embodiment is not particularly limited, but is preferably 0.01 to 3 mass %. The lower limit of the content is more preferably 0.03 mass % or more, still more preferably 0.05 mass % or more, and even more preferably 0.08 mass % or more. In addition, the upper limit of the content is more preferably 2 mass % or less, still more preferably 1 mass % or less, even more preferably 0.9 mass % or less, and yet further preferably 0.8 mass % or less. When the content of the accelerator is within the above range, the selectivity for SiGe, the suppression of damage to Si, and the defoaming properties can be further improved.

### (Corrosion Inhibitor)

The etching composition according to the present embodiment may contain a corrosion inhibitor as necessary in consideration of the metal species of the laminated substrate to be etched. The etching composition according to the present embodiment can be expected to achieve compatibility without reducing the effect of preventing corrosion of metals other than SiGe to be etched. Examples of the corrosion inhibitor may include at least one selected from the group consisting of a nitrogen-containing heterocyclic compound, a compound containing a mercapto group, an aliphatic amine compound, a zwitterionic compound, and salts thereof. These corrosion inhibitors are preferably those other than the amine compounds used as the accelerator described above.

The corrosion inhibitors may be used alone or in combination of two or more thereof.

A content of the corrosion inhibitor in the etching composition according to the present embodiment is not particularly limited, but is preferably 0.0001 to 1 mass %. The lower limit of the content is more preferably 0.0002 mass % or more, still more preferably 0.0003 mass % or more, and even more preferably 0.001 mass % or more. In addition, the upper limit of the content is more preferably 0.8 mass % or less, still more preferably 0.7 mass % or less, even more preferably 0.6 mass % or less, and yet further preferably 0.5 mass % or less.

### (pH Adjuster)

The etching composition according to the present embodiment may contain a pH adjuster in order to adjust the pH to a desired value. As the pH adjuster, inorganic acids, organic acids, organic basic compounds, and inorganic basic compounds can be appropriately used. For example, sulfuric acid, sulfurous acid, phosphoric acid, and the like are preferable.

The pH adjusters may be used alone or in combination of two or more thereof.

A content of the pH adjuster in the etching composition according to the present embodiment is not particularly limited, but is preferably 0.01 to 1 mass %. The lower limit of the content is more preferably 0.05 mass % or more, still more preferably 0.1 mass % or more, and even more preferably 0.15 mass % or more. In addition, the upper limit of the content is more preferably 0.8 mass % or less, still more preferably 0.6 mass % or less, even more preferably 0.5 mass % or less, and yet further preferably 0.3 mass % or less.

### (Solvent)

The etching composition according to the present embodiment may contain a solvent. For example, the solvent preferably contains water. The etching composition according to the present embodiment can be suitably used as an aqueous etching composition.

A content of water in the etching composition according to the present embodiment is not particularly limited, but is preferably 1 to 99 mass %. The lower limit of the content is more preferably 25 mass % or more, still more preferably 35 mass % or more, even more preferably 45 mass % or more, yet even more preferably 50 mass % or more, further preferably 55 mass % or more, yet further preferably 60 mass % or more, even further preferably 80 mass % or more, and most preferably 85 mass % or more. In addition, the upper limit of the content is more preferably 99 mass % or less. When the content of water is within the above range, the other components can be uniformly and stably dissolved, and the desired effects can be maintained while imparting water solubility as an aqueous etching composition.

In addition, the etching composition according to the present embodiment may contain an organic solvent. Specific examples of the organic solvent may include, but are not limited to, at least one selected from the group consisting of an alcohol-based solvent, a glycol ether-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an acetate-based solvent, a pyrrolidone-based solvent, and a urea-based solvent. Among them, at least one selected from the group consisting of an alcohol-based solvent, a glycol ether-based solvent, a sulfoxide-based solvent, a sulfone-based solvent, an amide-based solvent, an imidazolidinone-based solvent, a nitrile-based solvent, a ketone-based solvent, an ether-based solvent, a pyrrolidone-based solvent, and a urea-based solvent is preferable. In addition, when the etching composition according to the present embodiment contains an organic solvent, it is preferable to use a water-soluble organic solvent from the viewpoint of imparting water solubility.

### (Impurities and the Like)

The etching solution according to the present embodiment may contain, for example, a metal impurity containing at least one selected from the group consisting of Fe atoms, Cr atoms, Ni atoms, Zn atoms, Ca atoms, and Pb atoms.

The total content of the metal atoms in the etching solution according to the present embodiment is preferably 100 mass ppt or less with respect to the total mass of the etching solution. The lower limit value of the total content of the metal atoms is preferably as low as possible, and is, for example, 0.001 mass ppt or more. The total content of the metal atoms is, for example, 0.001 mass ppt to 100 mass ppt. By setting the total content of the metal atoms to be equal to or less than the above-described preferred upper limit value, it is considered that the defect suppressing property and the residue suppressing property of the etching solution are improved. By setting the total content of the metal atoms to be equal to or more than the above-described preferred lower limit value, it is considered that metal atoms are less likely to be present freely in the system, thereby reducing the likelihood of adversely affecting the overall manufacturing yield of the object to be etched.

The content of the metal impurities can be adjusted, for example, by a purification treatment such as filtering. The purification treatment such as filtering may be performed on a part or all of the raw materials before preparing the etching solution or may be performed after the etching solution is prepared.

The etching solution according to the present embodiment may contain, for example, impurities derived from organic substances (organic impurities). The total content of the organic impurities in the etching solution according to the present embodiment is preferably 5,000 mass ppm or less. The lower limit of the content of the organic impurities is preferably as low as possible, and is, for example, 0.1 mass ppm or more. Examples of the total content of the organic impurities may include 0.1 mass ppm to 5,000 mass ppm.

The etching solution according to the present embodiment may contain, for example, targets to be counted having a size countable by a light scattering type in-liquid particle counter. The size of the target to be counted is, for example, 0.04 μm or more. The number of the targets to be counted in the etching solution according to the present embodiment per 1 mL of the etching solution is, for example, 1,000 or less, and the lower limit value is, for example, 0.1 or more. It is considered that, when the number of targets to be counted in the etching solution is within the range described above, the effect of preventing metal corrosion, the effect of reducing defects, and the like by the etching solution are improved (however, the operations and effects of the present embodiment are not limited thereto).

The organic impurities and/or the targets to be counted described above may be added to the etching solution or may be inevitably mixed into the etching solution in a manufacturing step of the etching solution. Examples of cases where the organic impurities are inevitably mixed in the manufacturing step of the etching solution may include, but are not limited to, a case where the organic impurities are included in a raw material (e.g., an organic solvent) used for manufacturing the etching solution, and a case where the organic impurities are mixed from an external environment in the manufacturing step of the etching solution (e.g., contamination).

When the targets to be counted are added to the etching solution, an abundance ratio may be adjusted for each specific size considering surface roughness and the like of the object to be etched.

(pH)

A pH of the etching composition according to the present embodiment is not particularly limited, but is preferably 6 or less. The lower limit of the pH is preferably 1 or more, and more preferably 2 or more. The upper limit of the pH is more preferably 4.5 or less. For example, an example of a suitable combination of the upper limit and the lower limit of pH is 1 or more and 6 or less. When the pH is within the above range, the selectivity for SiGe, the suppression of damage to Si, and the defoaming properties can be further improved. The pH can be controlled to have a desired pH by adding the above-described pH adjuster or the like.

### <Etching Method>

The etching composition according to the present embodiment can be suitably used for etching of the laminated substrate described above. That is, examples of a preferred aspect of the etching method according to the present embodiment may include an etching method including etching a laminated substrate including a substrate and a layer provided on the substrate and containing a silicon germanium alloy (SiGe) using an etching composition (etching step), in which the etching composition contains (A) an oxidizing agent; (B) a compound capable of releasing fluoride ions or a salt thereof; and (C) a nonionic surfactant containing at least one selected from the group consisting of a compound (c1) represented by General Formula (c1) and a compound (c2) represented by General Formula (c2).

For the etching composition used in the etching method according to the present embodiment, the contents of the etching composition described above can be appropriately adopted. For the laminated substrate to be treated in the etching method according to the present embodiment, the configuration and other contents of the laminated substrate described in the etching composition can be appropriately adopted.

Note that, for the etching composition used in the etching method according to the present embodiment, it is preferable that, before the above-described etching step, a preparation step of preparing the etching composition is further included, the preparation step including mixing a first chemical solution containing the component (B) and the component (C) with a second chemical solution containing the component (A). By preparing the first chemical solution and the second chemical solution in advance and mixing them before the etching step (preferably immediately before the etching step) to prepare the etching composition, the etching composition can be used in a state in which the temporal decomposition of the oxidizing agent, which is the component (A), is effectively suppressed, thereby further improving the etching effect.

The first chemical solution may further contain other components in addition to the component (B) and the component (C), as long as they are components other than the component (A). For example, the first chemical solution may contain at least one selected from the group consisting of an accelerator, a corrosion inhibitor, a pH adjuster, and a solvent, as described above.

The second chemical solution may further contain other components in addition to the oxidizing agent, which is the component (A). For example, the second chemical solution may further contain the solvent described above. From the viewpoint of suppressing temporal decomposition of the oxidizing agent, it is preferable that the second chemical solution contains only an oxidizing agent and a solvent (e.g., water and/or an organic solvent). For example, it is preferable to use aqueous hydrogen peroxide as the second chemical solution.

Furthermore, another chemical solution (e.g., a third chemical solution or a fourth chemical solution) other than the first chemical solution and the second chemical solution may also be prepared, and the first chemical solution, the second chemical solution, and the other chemical solution may be mixed before the treatment step to prepare the processing solution. Examples of the other chemical solutions (e.g., a third chemical solution and a fourth chemical solution) may include chemical solutions containing, for example, other components such as a pH adjuster or a buffer described above and a solvent (e.g., water and/or an organic solvent).

As described above, when the first chemical solution and the second chemical solution are prepared separately, these chemical solutions can be used as an etching kit. That is, the etching method can further include, before the above-described treatment step, a step of preparing a processing solution kit containing a first chemical solution and a second chemical solution, and a step of preparing a processing solution by mixing the first chemical solution and the second chemical solution.

The treatment conditions of the etching method according to the present embodiment are not particularly limited, and appropriate conditions can be selected in consideration of the material and configuration of the laminated substrate to be etched and the level of the scale-up process. As the etching method, for example, an immersion method, a spray method, or a liquid-flooding method can be employed.

For example, the treatment temperature in the etching step is not particularly limited and may be 10 to 80° C. The lower limit of the treatment temperature may be 15° C. or higher or 20° C. or higher. In addition, the upper limit of the treatment temperature may be 70° C. or lower, 60° C. or lower, 50° C. or lower, 40° C. or lower, or 30° C. or lower.

For example, the treatment time in the etching step is not particularly limited and may be 10 seconds to 10 hours. The lower limit of the treatment time may be 30 seconds or more, 1 minute or more, 5 minutes or more, 10 minutes or more, 15 minutes or more, 20 minutes or more, 25 minutes or more, or 30 minutes or more. In addition, the upper limit of the treatment time may be 8 hours or less, 5 hours or less, 3 hours or less, 2 hours or less, or 1 hour or less.

It is preferable that the etching step in the etching method according to the present embodiment is a step of performing etching in an etching apparatus connected to a tank filled with the etching composition (etching solution). According to the present embodiment, since the etching composition has at least the above-described advantage of excellent defoaming properties, it is possible to effectively suppress the problem of bubbles that are likely to be generated when the etching composition that is subjected to etching in the etching apparatus is delivered to the tank, thereby effectively exhibiting advantages that could not be achieved by the conventional techniques.

As the etching method according to the present embodiment, it is preferable that the tank is provided with a circulation unit that refills, into the tank, the used etching composition that has been used for the etching treatment, and that the method includes a step of refilling the used etching composition into the tank again (reuse step). In this case, the method is suitably applied to a single-wafer etching step in which a first cycle of etching treatment is performed on a laminated substrate in the etching apparatus, the laminated substrate is taken out of the etching apparatus after the treatment, and then another laminated substrate is placed into the etching apparatus to perform a second cycle of etching treatment. The etching solution used in the first cycle (used etching solution) can be circulated and delivered again to the etching apparatus and used for the etching step in the second cycle.

As the etching method according to the present embodiment, it is preferable that the apparatus is provided with a processing unit that performs a regeneration treatment on the used etching composition and a circulation unit that refills, into the tank, the etching composition that is subjected to the regeneration treatment, and that the method includes a step of performing a regeneration treatment on the used etching composition used for the etching treatment by the processing unit (regeneration step) and a step of refilling, into the tank, the etching composition that is subjected to the regeneration treatment by the circulation unit. In this case, after the used etching composition is discharged from the tank, a step of filtering impurities in the etching composition and/or replenishing effective components (regeneration step) is performed. The etching composition regenerated in this manner can be delivered to the tank again and used for the etching step in the next cycle.

When the above-described reuse step or regeneration step is performed, undesirable foaming is likely to occur when the etching composition is delivered to the tank, and the foaming is likely to cause false detection by a water-level detection unit (e.g., a water-level meter or a level gauge) provided in the tank. However, since the etching composition of the present embodiment has excellent defoaming properties, such problems can be effectively suppressed.

It is preferable that the etching method according to the present embodiment includes a cleaning step of cleaning the laminated substrate before the etching step. The cleaning step can be performed using a known cleaning solution. Examples of the cleaning solution may include, for example, aqueous hydrogen fluoride (aqueous HF). The cleaning can be performed by bringing the cleaning solution into contact with the laminated substrate by a spin coating method, a dip method, a spray method, a paddle method, or the like. The cleaning can be performed at atmospheric pressure and at room temperature (about 15 to 30° C.). Examples of the contact time between the cleaning solution and the laminated substrate may include 10 to 180 seconds, 20 to 120 seconds, and 30 to 60 seconds.

It is preferable that the etching method according to the present embodiment includes a cleaning step and/or a drying step after the etching step. The cleaning step after the etching can be performed using a known cleaning solution. Examples of the cleaning solution may include water. The cleaning can be performed by bringing the cleaning solution into contact with the laminated substrate by a spin coating method, a dip method, a spray method, a paddle method, or the like. The cleaning can be performed at atmospheric pressure and at room temperature (about 15 to 30° C.). Examples of the contact time between the cleaning solution and the laminated substrate may include 10 to 180 seconds, 20 to 120 seconds, and 30 to 60 seconds. The drying step can employ a drying method such as natural drying or nitrogen blow drying.

### <Method for Manufacturing Semiconductor Substrate>

The etching composition and the etching method according to the present embodiment can be suitably used in a method for manufacturing a semiconductor substrate. Examples of a preferred aspect of the method for manufacturing a semiconductor substrate according to the present embodiment may include a method for manufacturing a semiconductor substrate, the method including: etching a laminated substrate including a substrate and a layer provided on the substrate and containing a silicon germanium alloy (SiGe) using an etching composition; and cleaning the etched laminated substrate with a cleaning solution, in which the etching composition contains (A) an oxidizing agent; (B) a compound capable of releasing fluoride ions or a salt thereof; and (C) a nonionic surfactant containing at least one selected from the group consisting of a compound (c1) represented by General Formula (c1) and a compound (c2) represented by General Formula (c2). For the etching composition used in the method for manufacturing a semiconductor substrate according to the present embodiment, the contents of the etching composition described above can be appropriately adopted. For the laminated substrate used in the method for manufacturing a semiconductor substrate according to the present embodiment, the configuration and other contents of the laminated substrate described in the etching composition can be appropriately adopted.

### EXAMPLES

The present invention is described in more detail with reference to the following examples and comparative examples, but the present invention is not limited to the following examples at all. Note that, unless otherwise specified, numerical values are on a mass basis.

### Examples 1 to 31 and Comparative Examples 1 to 4

Etching solutions having the compositions shown in the respective tables were prepared. For example, the etching solution of Example 1 contains 2 mass % hydrogen peroxide (H₂O₂), 0.1 mass % hydrogen fluoride (HF), 0.0005 mass % “Softanol 90” as a surfactant, 0.08 mass % “ACETYLENOL E40” as an additive, 0.08 mass % ethylenediamine (EDA), and the balance of water (deionized water, DIW).

### Component Names and Abbreviations

Note that supplementary explanations regarding the component names and abbreviations shown in the tables are provided below.

### (Surfactant)

Softanol 90: Nonionic surfactant manufactured by NIPPON SHOKUBAI CO., LTD., having the trade name “Softanol (registered trademark) 90”, which is a nonionic surfactant represented by the following formula and has a Griffin's calculated HLB value of 13.3 (an average number of added ethylene oxide units of 9) It is a surfactant having the structure of General Formula (c1) described above.

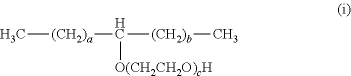

In the formula, a, b, and c each independently represent a number, a+b is 9 to 11, and c has an average value of 9.
“TERGITOL TMN-10”: Surfactant manufactured by Dow Inc., having the trade name “TERGITOL (trademark) TMN-10”, and represented by the following formula. It is a surfactant having the structure of General Formula (c1) described above.

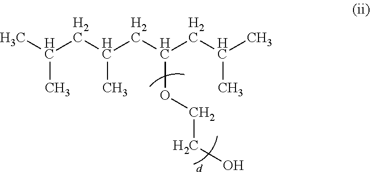

In the formula, d represents a number and has an average value of 11.
“P-PE61”: Surfactant manufactured by SINO-JAPAN CHEMICAL CO., LTD., having the trade name “P-PE61”, and having the structure of General Formula (c2) described above

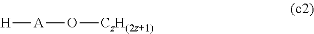

In the formula, A is a divalent group containing the structural unit (c2-1) represented by Formula (c2-1) and the structural unit (c2-2) represented by Formula (c2-2), the average number of added moles of the structural unit (c2-1) is 1, the average number of added moles of the structural unit (c2-2) is 6, and z represents a number of 8 to 16.

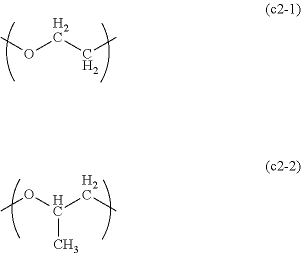

“Softanol EP9050”: Surfactant manufactured by NIPPON SHOKUBAI CO., LTD., having the trade name “Softanol (registered trademark) EP9050”, and having the structure of General Formula (c2) described above

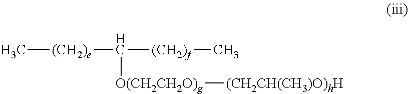

In the formula, g represents a number and has an average value of 5, h represents a number and has an average value of 9, e represents a number of 0 to 11, f represents a number of 0 to 11, and e+f=9 to 11.
“TERGITOL TMN-6”: Surfactant manufactured by Dow Inc., having the trade name “TERGITOL (trademark) TMN-6”, and represented by the following formula It is a surfactant having the structure of General Formula (c1) described above.

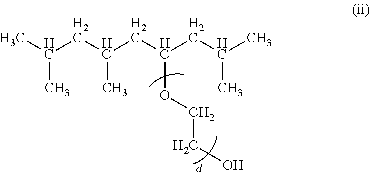

In the formula, d represents a number and has an average value of 8.
Softanol 50: Nonionic surfactant manufactured by NIPPON SHOKUBAI CO., LTD., having the trade name “Softanol (registered trademark) 50”, which is a nonionic surfactant represented by the following formula and has a Griffin's calculated HLB value of 10.5 It is a surfactant having the structure of General Formula (c1) described above. Note that the Griffin hydrophile-lipophile balance (HLB) value is one of the indices representing the degree of affinity of a surfactant for water and oil (an organic compound insoluble in water), and can be determined by 20×the total formula weight of the hydrophilic portion/the molecular weight.

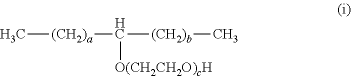

In the formula, a represents a number of 0 to 11, b represents a number of 0 to 11, c represents a number and has an average value of 5, and a+b=9 to 11.
Softanol 70: Nonionic surfactant manufactured by NIPPON SHOKUBAI CO., LTD., having the trade name “Softanol (registered trademark) 70”, which is a nonionic surfactant represented by the following formula and has a Griffin's calculated HLB value of 12.1 It is a surfactant having the structure of General Formula (c1) described above.

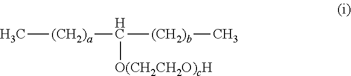

In the formula, a represents a number of 0 to 11, b represents a number of 0 to 11, c represents a number and has an average value of 5, and a+b=9 to 11.
“TERGITOL 15-S-5”: Surfactant manufactured by Dow Inc., having the trade name “TERGITOL (trademark) 15-S-5”, and represented by the following formula It is a surfactant having the structure of General Formula (c1) described above.

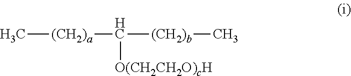

In the formula, a represents a number of 0 to 11, b represents a number of 0 to 11, c represents a number and has an average value of 5, and a+b=9 to 11.
“ACETYLENOL E00”: Acetylenic glycol manufactured by Kawaken Fine Chemicals Co., Ltd., having the trade name “ACETYLENOL (registered trademark) E00”, and having the structure represented by the following formula

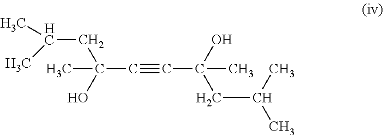 [SMILES: CC(C)CC(C)(O)C#CC(C)(O)CC(C)C]

“Triton X-100”: Polyethylene glycol octylphenyl ether manufactured by KISHIDA CHEMICAL CO., LTD., having the trade name “Triton (trademark) X-100”, and having the structure represented by the following formula

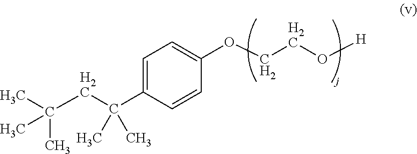

In the formula, j represents a number having an average value of 9 to 10.

### (Corrosion Inhibitor)

“ACETYLENOL E40”: Acetylenic glycol manufactured by Kawaken Fine Chemicals Co., Ltd., having the trade name “ACETYLENOL (registered trademark) E40”, and having the structure represented by the following formula

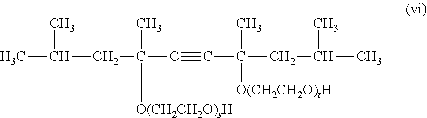

In the formula, s and t each independently represent a number, and the average value of s+t is 4.

<Measurement of pH>

The pH of the etching solution was measured using a pH/ORP meter (portable pH meter “ORION STAR A324”, manufactured by Thermo Fisher Scientific Inc.) under a temperature condition of 25° C.

### <Measurement of Etching Rate>

First, laminates (blanket wafers) each having a metal layer on a substrate were prepared as described below.
Laminate (blanket wafer) in which an SiGe₄₀ layer (a silicon germanium alloy having a concentration ratio of Si60:Ge40, film thickness: 20 nm) was deposited on a substrate (a 12-inch silicon substrate)
Laminate (blanket wafer) in which an SiGe₂₀ layer (a silicon germanium alloy having a concentration ratio of Si80:Ge20, film thickness: 20 nm) was deposited on a substrate (a 12-inch silicon substrate)
Laminate (blanket wafer) in which an Si layer (film thickness: 20 nm) was deposited on a substrate (a 12-inch silicon substrate)

Subsequently, each of the obtained laminates was cut into a size of 2 cm×2 cm in top view to obtain test samples (wafer coupons).

Then, as a pretreatment, the sample was immersed in 0.5 mass % aqueous hydrogen fluoride (aqueous HF) for 1 minute, and then cleaned and dried.

Thereafter, 100 mL of each etching solution of each of the Examples and Comparative Examples was placed in a 200-mL cup. Each sample was then introduced into the cup and treated by stirring at 300 rpm at a treatment temperature of 25° C. Note that the treatment time was 1 minute for the laminate including the SiGe₄₀ layer, 10 minutes for the laminate including the SiGe₂₀ layer, and 20 minutes for the laminate including the Si layer. After the treatment, each sample was taken out of the etching solution, washed with water at room temperature for 30 seconds, and dried by nitrogen blow.

Then, for SiGe₄₀, SiGe₂₀, and Si, the film reduction after the treatment was evaluated by measuring the etching rate (ER, Å/min) after the treatment relative to that before the treatment. A lower etching rate of the metal layer indicates that damage to the metal layer was more effectively suppressed. Note that the film thickness before the treatment and the film thickness after the treatment were measured by the following methods.
The film thicknesses of SiGe₄₀ and SiGe₂₀ were measured using a scanning X-ray fluorescence analyzer (“ZSX Primus IV”, manufactured by Rigaku Corporation).
The film thickness of Si was measured using an ellipsometer (“L115S300 STOKES WAFERSKAN”, manufactured by Gaertner Scientific Corporation).

### <Evaluation of Selectivity>

The selectivity of SiGe₄₀ to SiGe₂₀ (SiGe₄₀/SiGe₂₀) was determined by dividing the etching rate of SiGe₄₀ by the etching rate of SiGe₂₀. A larger value indicates better selectivity. The selectivity was evaluated according to the following criteria.
A: The selectivity value was 30 or more.
B: The selectivity value was less than 30.

### <Evaluation of Defoaming Properties>

In a 50-mL graduated cylinder, 25 mL of each etching solution of each of the Examples and Comparative Examples was placed, and shaking by hand was performed for 30 seconds. The shaking was performed under identical conditions among all the Examples and Comparative Examples. After the shaking, the time required for the foam to disappear was measured, and a shorter time was regarded as indicating better defoaming properties. The defoaming properties were evaluated according to the following criteria.
A: The foam disappeared in less than 5 minutes.
B: The foam disappeared in 5 minutes or more.

Table 1 shows the compositions and pH values of the etching solutions of Examples 1 to 17, and Table 2 shows the compositions and pH values of the etching solutions of Examples 18 to 31 and Comparative Examples 1 to 4. Table 3 shows the evaluation results of Examples 1 to 31 and Comparative Examples 1 to 4.

TABLE 1

| | Composition | | | | | |
|---|---|---|---|---|---|---|
| | Oxidizing agent | | Fluorine-based compound | | Surfactant | |
| | | Content | | Content | | Content |
| | Kind | [mass %] | Kind | [mass %] | Kind | [mass %] |
| Example 1 | Hydrogen peroxide | 2 | Hydrogen fluoride | 0.1 | Softanol 90 | 0.0005 |
| Example 2 | Hydrogen peroxide | 2 | Hydrogen fluoride | 0.1 | TERGITOL TMN-10 | 0.008 |
| Example 3 | Hydrogen peroxide | 2 | Hydrogen fluoride | 0.1 | P-PE61 | 0.1 |
| Example 4 | Hydrogen peroxide | 2 | Hydrogen fluoride | 0.1 | Softanol 90 | 0.0005 |
| Example 5 | Hydrogen peroxide | 2 | Hydrogen fluoride | 0.1 | TERGITOL TMN-10 | 0.008 |
| Example 6 | Hydrogen peroxide | 2 | Hydrogen fluoride | 0.1 | TERGITOL TMN-6 | 0.008 |
| Example 7 | Hydrogen peroxide | 2 | Hydrogen fluoride | 0.1 | Softanol 50 | 0.01 |
| Example 8 | Hydrogen peroxide | 2 | Hydrogen fluoride | 0.1 | Softano1 70 | 0.005 |
| Example 9 | Hydrogen peroxide | 2 | Hydrogen fluoride | 0.1 | TERGITOL 15-S-5 | 0.01 |
| Example 10 | Hydrogen peroxide | 2 | Hydrogen fluoride | 0.1 | Softanol EP9050 | 0.001 |
| Example 11 | Iodic acid | 0.3 | Hydrogen fluoride | 0.2 | TERGITOL TMN-10 | 0.008 |
| Example 12 | Periodic acid | 1 | Hydrogen fluoride | 0.2 | TERGITOL TMN-10 | 0.008 |
| Example 13 | Hydrogen peroxide | 5 | Tetramethylammonium | 0.8 | TERGITOL TMN-10 | 0.008 |
| | | | fluoride | | | |
| Example 14 | Hydrogen peroxide | 1 | Hydrogen fluoride | 0.1 | TERGITOL TMN-10 | 0.008 |
| Example 15 | Hydrogen peroxide | 3 | Hydrogen fluoride | 0.1 | TERGITOL TMN-10 | 0.008 |
| Example 16 | Hydrogen peroxide | 4 | Hydrogen fluoride | 0.1 | TERGITOL TMN-10 | 0.008 |
| Example 17 | Hydrogen peroxide | 5 | Hydrogen fluoride | 0.1 | TERGITOL TMN-10 | 0.008 |

| | Composition | | | | | | |
|---|---|---|---|---|---|---|---|
| | Corrosion inhibitor | | Accelerator | | | | |
| | | Content | | Content | Solvent | | |
| | Kind | [mass %] | Kind | [mass %] | Kind | Content | pH |
| Example 1 | ACETYLENOL E40 | | Ethylenediamine | 0.08 | Water | Balance | 3.6 |
| Example 2 | ACETYLENOL E40 | | Ethylenediamine | 0.08 | Water | Balance | 3.6 |
| Example 3 | — | | Ethylenediamine | 0.08 | Water | Balance | 3.6 |
| Example 4 | — | | Ethylenediamine | 0.08 | Water | Balance | 3.6 |
| Example 5 | — | | Ethylenediamine | 0.08 | Water | Balance | 3.6 |
| Example 6 | — | | Ethylenediamine | 0.08 | Water | Balance | 3.6 |
| Example 7 | — | | Ethylenediamine | 0.08 | Water | Balance | 3.6 |
| Example 8 | — | | Ethylenediamine | 0.08 | Water | Balance | 3.6 |
| Example 9 | — | | Ethylenediamine | 0.08 | Water | Balance | 3.6 |
| Example 10 | — | | Ethylenediamine | 0.08 | Water | Balance | 3.6 |
| Example 11 | — | | — | | Water | Balance | 2.3 |
| Example 12 | — | | — | | Water | Balance | 2.6 |
| Example 13 | Sulfuric acid | 0.2 | Ethylenediamine | 0.08 | Water | Balance | 3.6 |
| Example 14 | — | | Ethylenediamine | 0.08 | Water | Balance | 3.6 |
| Example 15 | — | | Ethylenediamine | 0.08 | Water | Balance | 3.6 |
| Example 16 | — | | Ethylenediamine | 0.08 | Water | Balance | 3.6 |
| Example 17 | — | | Ethylenediamine | 0.08 | Water | Balance | 3.6 |

TABLE 2

| | Composition | | | | | |
|---|---|---|---|---|---|---|
| | Oxidizing agent | | Fluorine-based compound | | Surfactant | |
| | | Content | | Content | | Content |
| | Kind | [mass %] | Kind | [mass %] | Kind | [mass %] |
| Example 18 | Hydrogen peroxide | 6 | Hydrogen fluoride | 0.1 | TERGITOL TMN-10 | 0.008 |
| Example 19 | Hydrogen peroxide | 7 | Hydrogen fluoride | 0.1 | TERGITOL TMN-10 | 0.008 |
| Example 20 | Hydrogen peroxide | 8 | Hydrogen fluoride | 0.1 | TERGITOL TMN-10 | 0.008 |
| Example 21 | Hydrogen peroxide | 9 | Hydrogen fluoride | 0.1 | TERGITOL TMN-10 | 0.008 |
| Example 22 | Hydrogen peroxide | 10 | Hydrogen fluoride | 0.1 | TERGITOL TMN-10 | 0.008 |
| Example 23 | Hydrogen peroxide | 2 | Hydrogen fluoride | 0.08 | TERGITOL TMN-10 | 0.008 |
| Example 24 | Hydrogen peroxide | 2 | Hydrogen fluoride | 0.12 | TERGITOL TMN-10 | 0.008 |
| Example 25 | Hydrogen peroxide | 2 | Hydrogen fluoride | 1 | TERGITOL TMN-10 | 0.008 |
| Example 26 | Hydrogen peroxide | 2 | Hydrogen fluoride | 0.1 | TERGITOL TMN-10 | 0.008 |
| Example 27 | Hydrogen peroxide | 2 | Hydrogen fluoride | 0.1 | TERGITOL TMN-10 | 0.008 |
| Example 28 | Hydrogen peroxide | 5 | Ammonium fluoride | 0.8 | TERGITOL TMN-10 | 0.008 |
| Example 29 | Hydrogen peroxide | 2 | Hydrogen fluoride | 6 | E40 | 0.1 |
| Example 30 | Hydrogen peroxide | 2 | Hydrogen fluoride | 4 | E40 | 0.1 |
| Example 31 | Hydrogen peroxide | 2 | Hydrogen fluoride | 2 | E40 | 0.1 |
| Comparative | Hydrogen peroxide | 2 | Hydrogen fluoride | 0.1 | — | |
| Example 1 | | | | | | |
| Comparative | Hydrogen peroxide | 2 | Hydrogen fluoride | 0.1 | ACETYLENOL E00 | 0.01 |
| Example 2 | | | | | | |
| Comparative | Hydrogen peroxide | 2 | Hydrogen fluoride | 0.1 | Dodecylbenzenesulfonic | 0.001 |
| Example 3 | | | | | acid | |
| Comparative | Hydrogen peroxide | 2 | Hydrogen fluoride | 0.1 | Triton X-100 | 0.001 |
| Example 4 | | | | | | |

| | Composition | | | | | | |
|---|---|---|---|---|---|---|---|
| | Corrosion inhibitor | | Accelerator | | | | |
| | | Content | | Content | Solvent | | |
| | Kind | [mass %] | Kind | [mass %] | Kind | Content | pH |
| Example 18 | — | | Ethylenediamine | 0.08 | Water | Balance | 3.6 |
| Example 19 | ACETYLENOL E40 | 0.08 | Ethylenediamine | 0.08 | Water | Balance | 3.6 |
| Example 20 | ACETYLENOL E40 | 0.08 | Ethylenediamine | 0.08 | Water | Balance | 3.6 |
| Example 21 | ACETYLENOL E40 | 0.08 | Ethylenediamine | 0.08 | Water | Balance | 3.6 |
| Example 22 | ACETYLENOL E40 | 0.08 | Ethylenediamine | 0.08 | Water | Balance | 3.6 |
| Example 23 | — | | Ethylenediamine | 0.08 | Water | Balance | 3.6 |
| Example 24 | — | | Ethylenediamine | 0.08 | Water | Balance | 3.6 |
| Example 25 | — | | Ethylenediamine | 0.8 | Water | Balance | 4 |
| Example 26 | — | | Ethylenediamine | 0.04 | Water | Balance | 3.2 |
| Example 27 | — | | Ethylenediamine | 0.15 | Water | Balance | 4.1 |
| Example 28 | Sulfuric acid | 0.54 | — | | Water | Balance | 4 |
| Example 29 | | | EDA | 5 | Water | Balance | 4 |
| Example 30 | | | EDA | 3.3 | Water | Balance | 4 |
| Example 31 | | | EDA | 1.7 | Water | Balance | 4 |
| Comparative | — | | Ethylenediamine | 0.08 | Water | Balance | 3.6 |
| Example 1 | | | | | | | |
| Comparative | — | | Ethylenediamine | 0.08 | Water | Balance | 3.6 |
| Example 2 | | | | | | | |
| Comparative | — | | Ethylenediamine | 0.08 | Water | Balance | 3.6 |
| Example 3 | | | | | | | |
| Comparative | — | | Ethylenediamine | 0.08 | Water | Balance | 3.6 |
| Example 4 | | | | | | | |

TABLE 3

| | Treatment | Etching rate | | | Selectivity | | Defoaming |
|---|---|---|---|---|---|---|---|
| | temperature | [Å/min] | | | SiGe40/ | | properties |
| | [° C.] | SiGe40 | SiGe20 | Si | SiGe20 | Evaluation | Evaluation |
| Example 1 | 25 | 89 | 1.1 | <0.5 | 80.9 | A | A |
| Example 2 | 25 | 95 | 0.7 | <0.5 | 135.7 | A | A |
| Example 3 | 25 | 72 | 1.3 | <0.5 | 55.4 | A | A |
| Example 4 | 25 | 90 | 2.3 | <0.5 | 39.1 | A | A |
| Example 5 | 25 | 93 | 2.2 | <0.5 | 42.3 | A | A |
| Example 6 | 25 | 93 | 2.2 | <0.5 | 42.3 | A | A |
| Example 7 | 25 | 91 | 2.6 | <0.5 | 35.0 | A | A |
| Example 8 | 25 | 92 | 2.4 | <0.5 | 38.3 | A | A |
| Example 9 | 25 | 91 | 2.3 | <0.5 | 39.6 | A | A |
| Example 10 | 25 | 111 | 1.5 | <0.5 | 74.0 | A | A |
| Example 11 | 25 | 186 | 3.828 | <0.5 | 48.6 | A | A |
| Example 12 | 25 | 70 | 1.9 | <0.5 | 36.8 | A | A |
| Example 13 | 25 | 144 | 3.168 | <0.5 | 45.5 | A | A |
| Example 14 | 25 | 57.241 | 1.2 | <0.5 | 47.7 | A | A |
| Example 15 | 25 | 89 | 1.9 | <0.5 | 46.8 | A | A |
| Example 16 | 25 | 105 | 2.2 | <0.5 | 47.7 | A | A |
| Example 17 | 25 | 120 | 2.6 | <0.5 | 46.2 | A | A |
| Example 18 | 25 | 137 | 3.9 | <0.5 | 35.1 | A | A |
| Example 19 | 25 | 153 | 3.3 | <0.5 | 46.4 | A | A |
| Example 20 | 25 | 169 | 4.6 | <0.5 | 36.7 | A | A |
| Example 21 | 25 | 185 | 5.9 | <0.5 | 31.4 | A | A |
| Example 22 | 25 | 210 | 6.9 | <0.5 | 30.4 | A | A |
| Example 23 | 25 | 108 | 2.3 | <0.5 | 47.0 | A | A |
| Example 24 | 25 | 112 | 2.5 | <0.5 | 44.8 | A | A |
| Example 25 | 25 | 120 | 1.1 | <0.5 | 109.1 | A | A |
| Example 26 | 25 | 47 | 1 | <0.5 | 47.0 | A | A |
| Example 27 | 25 | 113 | 3.7 | <0.5 | 30.5 | A | A |
| Example 28 | 25 | 176 | 2.8 | <0.5 | 62.9 | A | A |
| Example 29 | 25 | 42 | 1 | <0.5 | 42.0 | A | A |
| Example 30 | 25 | 74 | 0.7 | <0.5 | 105.7 | A | A |
| Example 31 | 25 | 116 | 1.2 | <0.5 | 96.7 | A | A |
| Comparative | 25 | 98 | 4.6 | <0.5 | 21.3 | B | A |
| Example 1 | | | | | | | |
| Comparative | 25 | 92 | 4.2 | <0.5 | 21.9 | B | A |
| Example 2 | | | | | | | |
| Comparative | 25 | 105 | 1.6 | <0.5 | 65.6 | A | B |
| Example 3 | | | | | | | |
| Comparative | 25 | 101 | 2.1 | <0.5 | 48.1 | A | B |
| Example 4 | | | | | | | |

From the above, according to the present Examples, it was confirmed at least that the etching composition has excellent selectivity for SiGe, excellent suppression of damage to Si, and excellent defoaming properties.

What is claimed is:

1. An etching composition comprising:
(A) an oxidizing agent;
(B) a compound capable of releasing fluoride ions or a salt thereof; and
(C) a nonionic surfactant comprising at least one selected from the group consisting of a compound (c1) represented by the following General Formula (c1) and a compound (c2) represented by the following General Formula (c2): 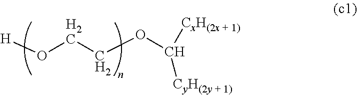
in General Formula (c1), x, y, and n represent numbers of 1 or more, and 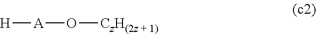
in General Formula (c2), A is a divalent group comprising a structural unit (c2-1) represented by the following Formula (c2-1) and a structural unit (c2-2) represented by the following Formula (c2-2), and z represents a number of 1 or more.

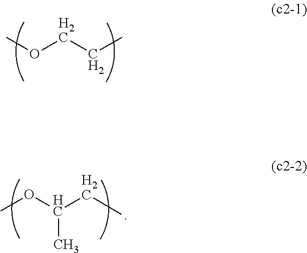

2. The etching composition according to claim 1, wherein
the component (A) includes at least one selected from the group consisting of hydrogen peroxide and an oxo acid.

3. The etching composition according to claim 1, wherein
the component (B) is at least one selected from the group consisting of hydrogen fluoride, ammonium fluoride, ammonium hydrogen fluoride, triethanolammonium fluoride, diglycolammonium fluoride, methyldiethanolammonium fluoride, tetramethylammonium fluoride, triethylamine trihydrofluoride, fluoroboric acid, tetrafluoroboric acid, ammonium tetrafluoroborate, fluoroacetic acid, ammonium fluoroacetate, trifluoroacetic acid, fluorosilicic acid, ammonium fluorosilicate, and tetrabutylammonium tetrafluoroborate.

4. The etching composition according to claim 1, wherein
a content of the component (A) is 0.01 to 20 mass %.

5. The etching composition according to claim 4, wherein
a content of the component (B) is 0.01 to 10 mass %.

6. The etching composition according to claim 1, wherein
a content of the component (C) is 0.0001 to 3 mass %.

7. The etching composition according to claim 1, further comprising
water.

8. The etching composition according to claim 7, wherein
the etching composition has a pH of 6 or less.

9. The etching composition according to claim 1, wherein
the etching composition is an etching composition for selectively etching a layer containing a silicon germanium alloy (SiGe).

10. An etching method comprising etching a laminated substrate including a substrate and a layer provided on the substrate and comprising a silicon germanium alloy (SiGe) using an etching composition,
wherein the etching composition comprises:
(A) an oxidizing agent;
(B) a compound capable of releasing fluoride ions or a salt thereof; and
(C) a nonionic surfactant containing at least one selected from the group consisting of a compound (c1) represented by the following General Formula (c1) and a compound (c2) represented by the following General Formula (c2): 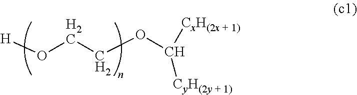
in General Formula (c1), x, y, and n represent numbers of 1 or more, 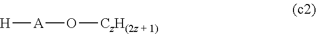
in General Formula (c2), A is a divalent group comprising a structural unit (c2-1) represented by the following Formula (c2-1) and a structural unit (c2-2) represented by the following Formula (c2-2), and z represents a number of 1 or more.

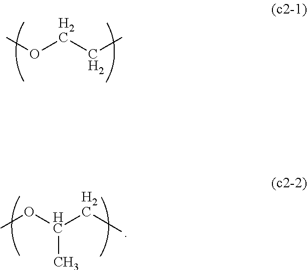

11. A method for manufacturing a semiconductor substrate, the method comprising:
etching a laminated substrate including a substrate and a layer provided on the substrate and comprising a silicon germanium alloy (SiGe) using an etching composition; and
cleaning the etched laminated substrate with a cleaning solution,
wherein the etching composition comprises:
(A) an oxidizing agent;
(B) a compound capable of releasing fluoride ions or a salt thereof; and
(C) a nonionic surfactant containing at least one selected from the group consisting of a compound (c1) represented by the following General Formula (c1) and a compound (c2) represented by the following General Formula (c2): 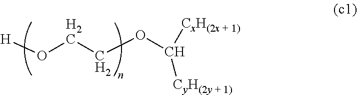
in General Formula (c1), x, y, and n represent numbers of 1 or more, and 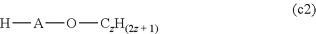
in General Formula (c2), A is a divalent group comprising a structural unit (c2-1) represented by the following Formula (c2-1) and a structural unit (c2-2) represented by the following Formula (c2-2), and z represents a number of 1 or more. [chemical structure]
